(19) United States
(12) Patent Application Publication
(10) Pub. No.: US 2026/0343812 A1
(43) Pub. Date: Oct. 29, 2026

(54) LIQUID COOLING HEAT DISSIPATION MODULE

(71) Applicant: COOLER MASTER CO., LTD., Taipei City (TW)

(72) Inventor: Chun-Ching HO, Taipei City (TW)

(73) Assignee: COOLER MASTER CO., LTD., Taipei City (TW)

(21) Appl. No.: 19/565,202

(22) Filed: Mar. 12, 2026

(30) Foreign Application Priority Data
Apr. 25, 2025 (TW) 114115786
Jul. 31, 2025 (TW) 114129115

(51) Int. Cl. H05K 7/20

(52) U.S. Cl. CPC H05K 7/20272; H05K 7/20254; H05K 7/20772

(57) ABSTRACT

A liquid cooling heat dissipation module includes a manifold assembly configured to be in fluid communication with a heat exchanger and to distribute and collect a working fluid. The liquid cooling heat dissipation module also includes a first cold plate in fluid communication with the manifold assembly. The first cold plate is configured to thermally contact heat-generating components disposed on a first surface of the mainboard. The liquid cooling heat dissipation module further includes a second cold plate in fluid communication with the manifold assembly. The second cold plate is configured to thermally contact heat-generating components disposed on a second surface of the mainboard. The first cold plate is pivotally coupled to the manifold assembly, and the second cold plate is securely connected to the manifold assembly.

### CROSS-REFERENCE TO RELATED APPLICATIONS

This application claims priority to Taiwan Patent Application Nos. 114115786, filed on Apr. 25, 2025, and 114129115, filed on Jul. 31, 2025, each of which is incorporated herein by reference in its entirety.

### TECHNICAL FIELD

The present disclosure relates to a liquid cooling heat dissipation module for electronic devices.

### BACKGROUND

With the advancement of electronic technologies, a wide variety of electronic devices and systems have been developed, and the demand for processing capability has increased significantly. To meet higher performance requirements, electronic devices increasingly employ components with greater power consumption. However, components operating at higher power levels generate greater amounts of heat, which requires more efficient heat dissipation solutions to maintain reliability and performance.

Conventional single-sided printed circuit boards have restricted wiring space, making it difficult to accommodate high-density circuitry. Such limits may have an adverse effect on signal integrity, and the relatively large board size is contradictory with the trend toward miniaturization of electronic devices. In addition, heat dissipation for high-power components mounted on single-sided printed circuit boards is challenging, and the mechanical strength of such boards is relatively low, rendering them more vulnerable to damage caused by vibration or mechanical stress.

To address these issues, double-sided printed circuit boards have been developed, in which circuit traces and electronic components may be arranged on both upper and lower surfaces of the double-sided printed circuit boards. This configuration increases circuit density, reduces overall size and weight, improves signal integrity and resistance to interference, and allows high-power components to be distributed across both surfaces to improve heat dissipation efficiency. However, conventional cooling heat sinks and cooling modules are primarily designed for heat-generating components located on a single surface. When such cooling solutions are applied to the double-sided printed circuit boards, problems such as installation difficulty and non-uniform heat dissipation may occur. Therefore, it is still necessary to address the cooling solutions for the double-sided printed circuit boards.

### SUMMARY

One aspect of the present disclosure provides a liquid cooling heat dissipation module. The liquid cooling heat dissipation module includes a manifold assembly configured to be in fluid communication with a heat exchanger and to distribute and collect a working fluid. The liquid cooling heat dissipation module also includes a first cold plate in fluid communication with the manifold assembly. The first cold plate is configured to thermally contact heat-generating components that are disposed on a first surface of the mainboard. The liquid cooling heat dissipation module further includes a second cold plate in fluid communication with the manifold assembly. The second cold plate is configured to thermally contact heat-generating components disposed on a second surface of the mainboard. The first cold plate is pivotally coupled to the manifold assembly, and the second cold plate is securely connected to the manifold assembly.

In some embodiments, the first cold plate is movable relative to the second cold plate to position the liquid cooling heat dissipation module in the open state or the closed state, when the liquid cooling heat dissipation module is in the open state, an included angle between the first cold plate and the second cold plate is greater than 0 degrees and less than or equal to 90 degrees, and when the liquid cooling heat dissipation module is in the closed state, the included angle between the first cold plate and the second cold plate is 0 degrees.

In some embodiments, the manifold assembly includes a distribution manifold having a main inlet port in fluid communication with two distribution ports. The manifold assembly also includes a collection manifold having a main outlet port in fluid communication with two collection ports.

In some embodiments, the liquid cooling heat dissipation module further includes a main inlet conduit having opposing ends respectively connected to the main inlet port and the heat exchanger, a main outlet conduit having opposing ends respectively connected to the main outlet port and the heat exchanger, and two first nozzles respectively rotatably coupled to a first distribution port and a first collection port.

In some embodiments, the first cold plate includes an internal flow channel having opposite ends respectively connected to the two first nozzles via two connecting pipes, and the second cold plate includes a metal plate body and a metal tube embedded in the metal plate body, opposite ends of the metal tube being securely connected to a second distribution port and a second collection port.

In some embodiments, the liquid cooling heat dissipation module further includes at least one flow-guiding conduit in fluid communication with the manifold assembly. The first cold plate and the second cold plate are fluidly coupled to the heat exchanger through the manifold assembly and the at least one flow-guiding conduit to define at least one cooling loop.

In some embodiments, the liquid cooling heat dissipation module further includes a foldable handle pivotally disposed on the first cold plate.

In some embodiments, the liquid cooling heat dissipation module further includes a plurality of fasteners extending through the first cold plate and the second cold plate and securing the first cold plate and the second cold plate to the mainboard when the liquid cooling heat dissipation module is in the closed state.

Another aspect of the present disclosure provides a liquid cooling heat dissipation module. The liquid cooling heat dissipation module includes a manifold assembly having a distribution manifold and a collection manifold. The liquid cooling dissipation module also includes a first cold plate in fluid communication with the manifold assembly. The first cold plate is configured to thermally contact heat-generating components disposed on a first surface of the mainboard. The liquid cooling dissipation module further includes a second cold plate in fluid communication with the manifold assembly. The second cold plate is configured to thermally contact heat-generating components disposed on a second surface of the mainboard. Both the first cold plate and the second cold plate are pivotally coupled to the manifold assembly.

In some embodiments, when the liquid cooling heat dissipation module is in the open state, an included angle between the first cold plate and the second cold plate is greater than 0 degrees and less than or equal to 180 degrees, and when the liquid cooling heat dissipation module is in the closed state, the included angle between the first cold plate and the second cold plate is 0 degrees.

In some embodiments, the first cold plate is rotatable about a first axis extending through the manifold assembly, the second cold plate is rotatable about a second axis extending through the manifold assembly, and the first axis is parallel to the second axis.

In some embodiments, the liquid cooling heat dissipation module further includes a main inlet conduit and a main outlet conduit. One end of the main inlet conduit and one end of the main outlet conduit are respectively connected to the heat exchanger.

In some embodiments, the liquid cooling heat dissipation module further includes two first nozzles rotatable along the first axis, and two second nozzles rotatable along the second axis. The first cold plate includes a first internal flow channel connected to the two first nozzles via connecting pipes, and the second cold plate comprises a metal plate body and a metal tube having opposite ends securely connected to the two second nozzles.

In some embodiments, the liquid cooling heat dissipation module further includes at least one flow-guiding conduit in fluid communication with the manifold assembly. The first cold plate and the second cold plate are fluidly coupled to the heat exchanger through the manifold assembly and the at least one flow-guiding conduit to form at least one cooling loop.

In some embodiments, the liquid cooling heat dissipation module further includes a foldable handle pivotally disposed on the first cold plate.

Still another aspect of the present disclosure provides a server. The server includes a mainboard having a first surface and a second surface opposite the first surface. The server also includes a plurality of heat-generating components disposed on the first surface and the second surface. The server further includes a liquid cooling heat dissipation module. The liquid cooling heat dissipation module includes a manifold assembly configured to be in fluid communication with a heat exchanger and to distribute and collect a working fluid. The liquid cooling heat dissipation module also includes a first cold plate in fluid communication with the manifold assembly. The first cold plate is configured to thermally contact heat-generating components disposed on the first surface of the mainboard. The liquid cooling heat dissipation module further includes a second cold plate in fluid communication with the manifold assembly. The second cold plate being configured to thermally contact heat-generating components on the second surface of the mainboard. The first cold plate is pivotally coupled to the manifold assembly, and the second cold plate is securely connected to the manifold assembly.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a partial perspective view of a server and a liquid cooling heat dissipation module thereof in a closed state, in accordance with one embodiment of the present disclosure.

FIG. 2 is a partial exploded view of the server and the liquid cooling heat dissipation module of FIG. 1 in an open state.

FIG. 3 is another partial exploded view of the server and the liquid cooling heat dissipation module of FIG. 1 in the open state.

FIG. 4 is a partially enlarged exploded view of the liquid cooling heat dissipation module of FIG. 1.

FIG. 5 is another partially enlarged exploded view of the liquid cooling heat dissipation module of FIG. 1.

FIG. 6 is a side view of the server and the liquid cooling heat dissipation module of FIG. 1 in the open state.

FIG. 7 is a perspective view of the liquid cooling heat dissipation module of FIG. 1, illustrating a foldable handle in a folded position.

FIG. 8 is a partial perspective view of a server and a liquid cooling heat dissipation module thereof in a closed state, in accordance with one embodiment of the present disclosure.

FIG. 9 is a perspective view of the server and the liquid cooling heat dissipation module of FIG. 8 in an open state.

FIG. 10 is another perspective view of the server and the liquid cooling heat dissipation module of FIG. 8 in the open state.

FIG. 11 is an exploded view of the liquid cooling heat dissipation module of FIG. 8.

FIG. 12 is another exploded view of the liquid cooling heat dissipation module of FIG. 8.

FIG. 13 is a top view of a manifold assembly of FIG. 11 with an upper cover removed.

FIG. 14 is a side view of the server and the liquid cooling heat dissipation module of FIG. 8 in the open state.

FIG. 15 is a perspective view of the liquid cooling heat dissipation module of FIG. 8, illustrating a foldable handle in a folded position.

FIG. 16 is a top view of a manifold assembly with an upper cover removed in accordance with one embodiment of the present disclosure.

### DETAILED DESCRIPTION OF EMBODIMENTS

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

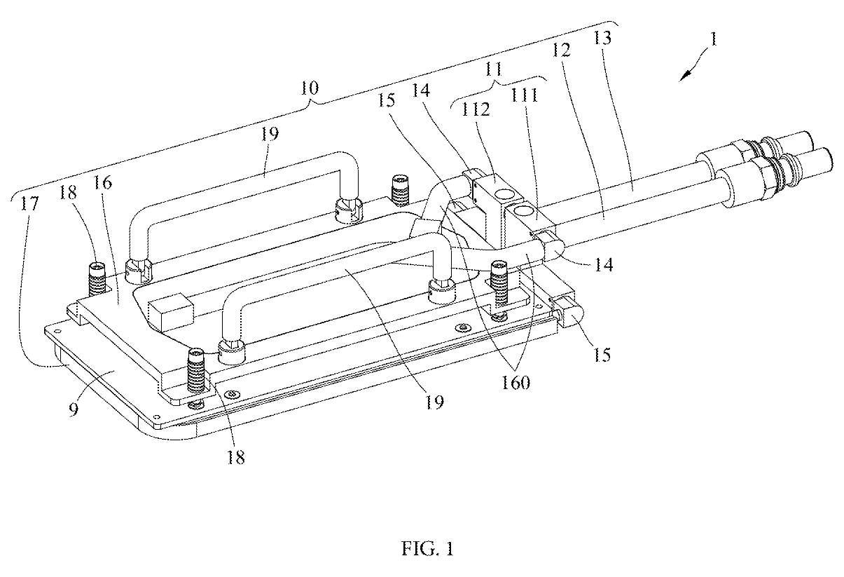

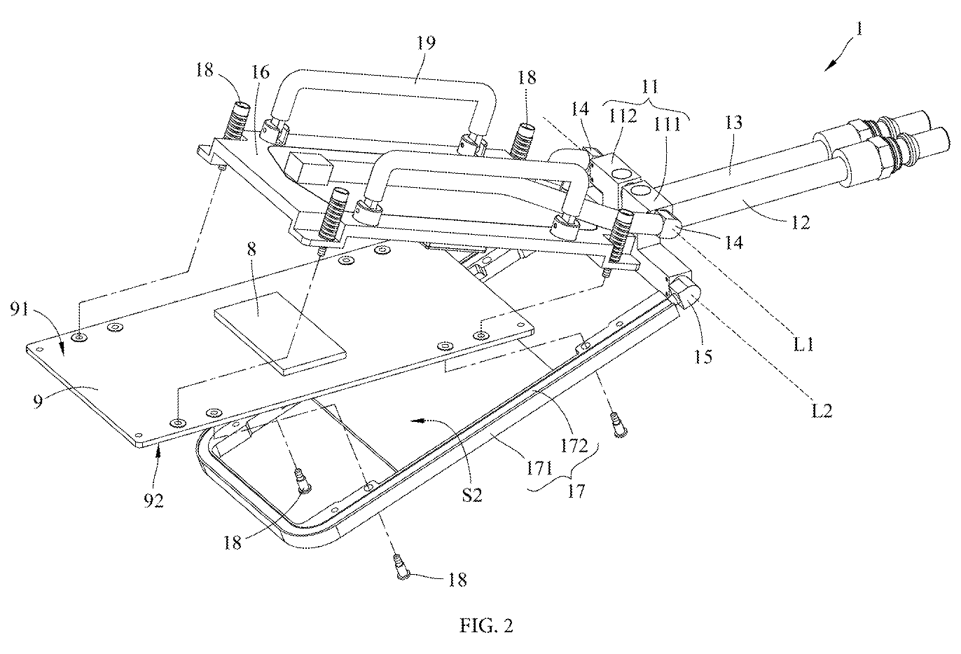

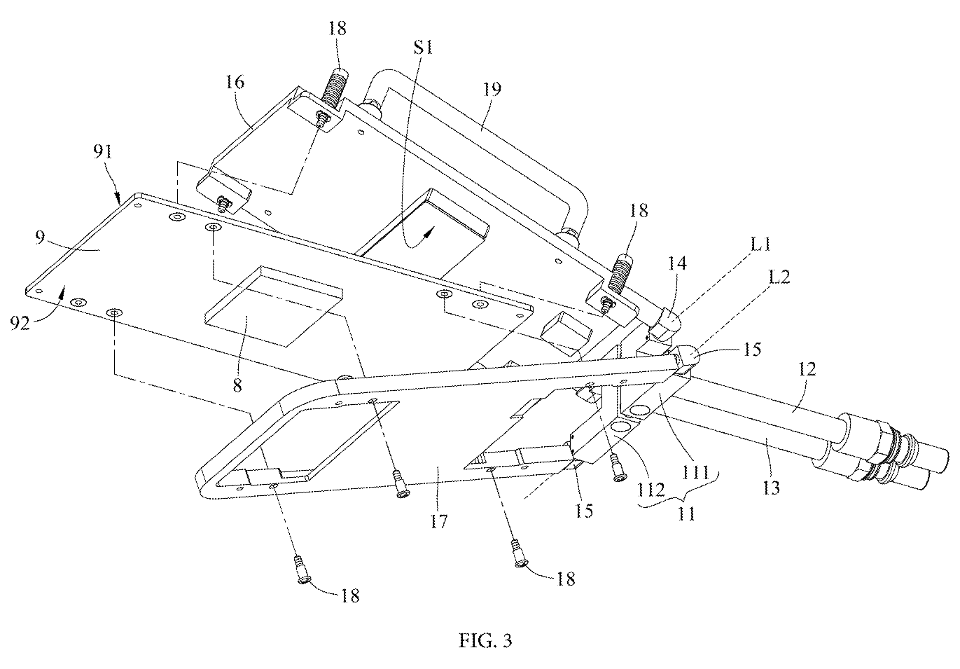

Referring to FIGS. 1-3, FIG. 1 is a partial perspective view of a server 1 and a liquid cooling heat dissipation module 10 thereof in a closed state, in accordance with one embodiment of the present disclosure. FIG. 2 is a partial exploded view of the server 1 and the liquid cooling heat dissipation module 10 of FIG. 1 in an open state. FIG. 3 is another partial exploded view of the server 1 and the liquid cooling heat dissipation module 10 of FIG. 1 in the open state.

In one embodiment, the server 1 includes a mainboard 9, a plurality of heat-generating components 8, and a liquid cooling heat dissipation module 10. The mainboard 9 has a first surface 91 and a second surface 92 opposite to each other, and the heat-generating components 8 are respectively coupled to the first surface 91 and the second surface 92. The liquid cooling heat dissipation module 10 is configured to cool the heat-generating components 8 located on the opposite surfaces of the mainboard 9. The heat-generating components 8 may include a central processing unit (CPU), a graphics processing unit (GPU), or any suitable electronic devices.

In one embodiment, the liquid cooling heat dissipation module 10 includes a manifold assembly 11, a main inlet conduit 12, a main outlet conduit 13, two first nozzles 14, two second nozzles 15, a first cold plate 16, a second cold plate 17, a plurality of fasteners 18, and two foldable handles 19. The manifold assembly 11 is configured to be in fluid communication with a heat exchanger (not separately shown) and to distribute and collect working fluid.

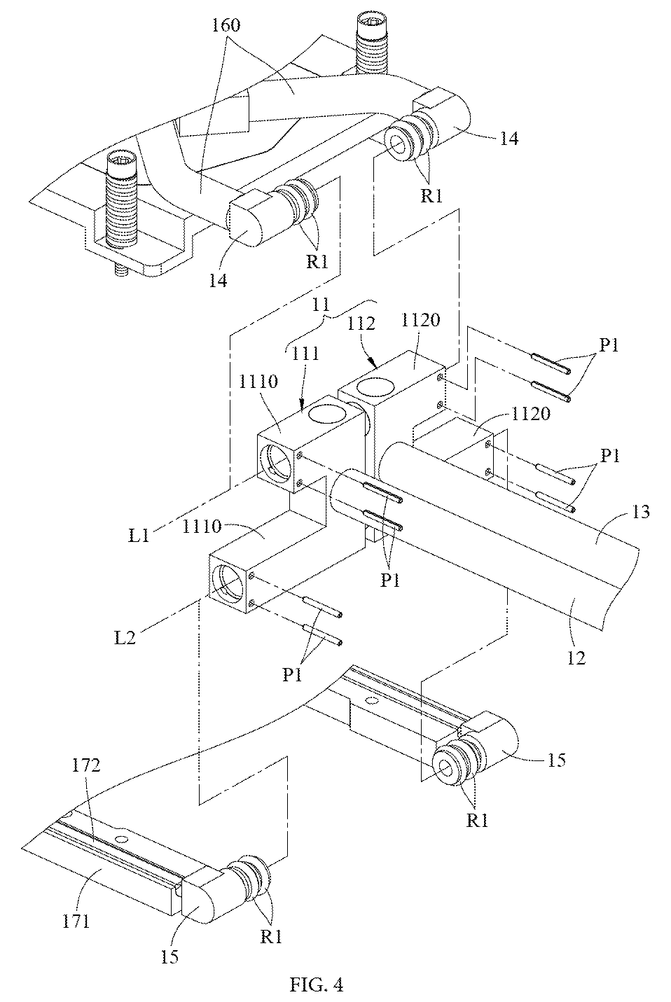

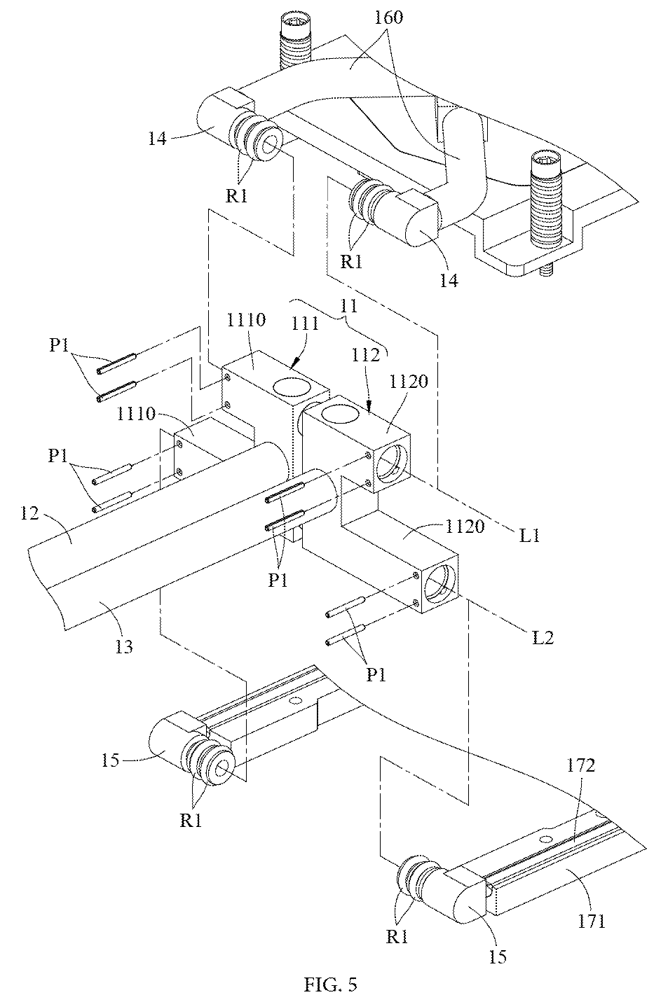

Referring to FIGS. 4-5, FIG. 4 is a partially enlarged exploded view of the liquid cooling heat dissipation module 10 of FIG. 1. FIG. 5 is another partially enlarged exploded view of the liquid cooling heat dissipation module 10 of FIG. 1.

In one embodiment, the manifold assembly 11 includes a distribution manifold 111 and a collection manifold 112. The distribution manifold 111 has a main inlet port (not separately numbered) in fluid communication with two distribution ports 1110, and the collection manifold 112 has a main outlet port (not separately numbered) in fluid communication with two collection ports 1120. Specifically, the distribution manifold 111 is configured to distribute working fluid flowing from the main inlet port to the two distribution ports 1110, and the collection manifold 112 is configured to collect the working fluid flowing from the two collection ports 1120 into the main outlet port. In this embodiment, the distribution manifold 111 and the collection manifold 112 are fixedly connected to each other. However, the embodiment is not limited thereto. In other embodiments, the distribution manifold and the collection manifold of the manifold assembly can be provided separately.

In one embodiment, opposite ends of the main inlet conduit 12 are respectively connected to the main inlet port of the distribution manifold 111 and to a heat exchanger, guiding the working fluid cooled by the heat exchanger to the distribution manifold 111 of the manifold assembly 11. Opposite ends of the main outlet conduit 13 are respectively connected to the main outlet port of the collection manifold 112 and to the heat exchanger, guiding the heated working fluid from the collection manifold 112 of the manifold assembly 11 to the heat exchanger.

In one embodiment, two first nozzles 14 are respectively rotatably coupled to one distribution port 1110 of the distribution manifold 111 and to one collection port 1120 of the collection manifold 112 along a first axis L1. The first axis L1 extends through the manifold assembly 11, passing through the one distribution port 1110 and the one collection port 1120.

In one embodiment, two second nozzles 15 are respectively rotatably coupled to the other distribution port 1110 of the distribution manifold 111 and to the other collection port 1120 of the collection manifold 112 along a second axis L2. The second axis L2 extends through the manifold assembly 11, passing through the other distribution port 1110 and the other collection port 1120. The first axis L1 is different from the second axis L2, and in some examples, the first axis L1 is parallel to the second axis L2.

As shown in FIGS. 4 and 5, the first nozzles 14 and the second nozzles 15 are barb-type nozzles having multiple barbed layers, and a plurality of sealing rings R1 are fixedly sleeved on the barbed portions of the first nozzles 14 and the second nozzles 15. After the barbed portions of the first nozzles 14 and the second nozzles 15 are inserted into the distribution ports 1110 and the collection ports 1120, pins P1 are inserted into the distribution ports 1110 and the collection ports 1120 so as to interfere with the barbed structures in an insertion direction, preventing the barbed nozzles from being unintentionally disengaged from the distribution ports 1110 or the collection ports 1120 and simultaneously preventing leakage of the working fluid. Additionally, the first and second nozzles 14, 15 and the pins P1 do not interfere with each other in a circumferential direction of the barbed portions, allow the first and second nozzles 14, 15 to rotate freely within the distribution ports 1110 or the collection ports 1120.

Also referring to FIGS. 1-3, the first cold plate 16 is in fluid communication with the manifold assembly 11 to allow the working fluid to flow therethrough, and the first cold plate 16 is configured to be in thermal contact with the heat-generating components 8 on the first surface 91 of the mainboard 9. Specifically, the first cold plate 16 includes a first internal flow channel and a first heat-absorbing surface S1. Two opposite ends of the first internal flow channel are respectively connected to two connecting pipes 160, and the ends of the connecting pipes 160 distal from the first internal flow channel are securely connected to the two first nozzles 14, such that the first internal flow channel of the first cold plate 16 is in fluid communication with the manifold assembly 11 through the connecting pipes 160 and the first nozzles 14. The first heat-absorbing surface S1 is in thermal contact with the heat-generating components 8 on the first surface 91 of the mainboard 9, conducting heat generated by the heat-generating components 8 to the working fluid in the first internal flow channel through the first heat-absorbing surface S1. In one embodiment, the connecting pipes 160 can be made of metal or any other suitable materials.

Further referring to FIGS. 1-3, the second cold plate 17 is in fluid communication with the manifold assembly 11 to allow the working fluid to flow therethrough, and the second cold plate 17 is in thermal contact with the heat-generating components 8 on the second surface 92 of the mainboard 9. Specifically, the second cold plate 17 includes a metal plate body 171 and a metal tube 172. The metal tube 172 is partially embedded in the metal plate body 171, and two opposite ends of the metal tube 172 protrude from the metal plate body 171 and are respectively fixedly connected to the two second nozzles 15, allowing the metal tube 172 of the second cold plate 17 to fluidly communicate with the manifold assembly 11 through the second nozzles 15. The metal plate body 171 has a second heat-absorbing surface S2 configured to be in thermal contact with the heat-generating components 8 on the second surface 92 of the mainboard 9, conducting heat generated by the heat-generating components 8 to the working fluid within the metal tube 172 through the second heat-absorbing surface S2. In one embodiment, the metal tube 172 can be made of copper or other suitable materials, and the metal plate body 171 can be made of aluminum, copper or other suitable materials.

Accordingly, the first cold plate 16 and the second cold plate 17 are both pivotally coupled to the manifold assembly 11, and the first cold plate 16 and the second cold plate 17 cooperate with the manifold assembly 11 and the heat exchanger to form two parallel cooling loops. The first cold plate 16 and the second cold plate 17 are movable relative to each other to position the liquid cooling heat dissipation module 10 in a closed state or an open state. According to the embodiments, the first cold plate 16 and the second cold plate 17 have different structures. However, the embodiment is not limited thereto. In other embodiments, the first cold plate and the second cold plate may have substantially identical structures.

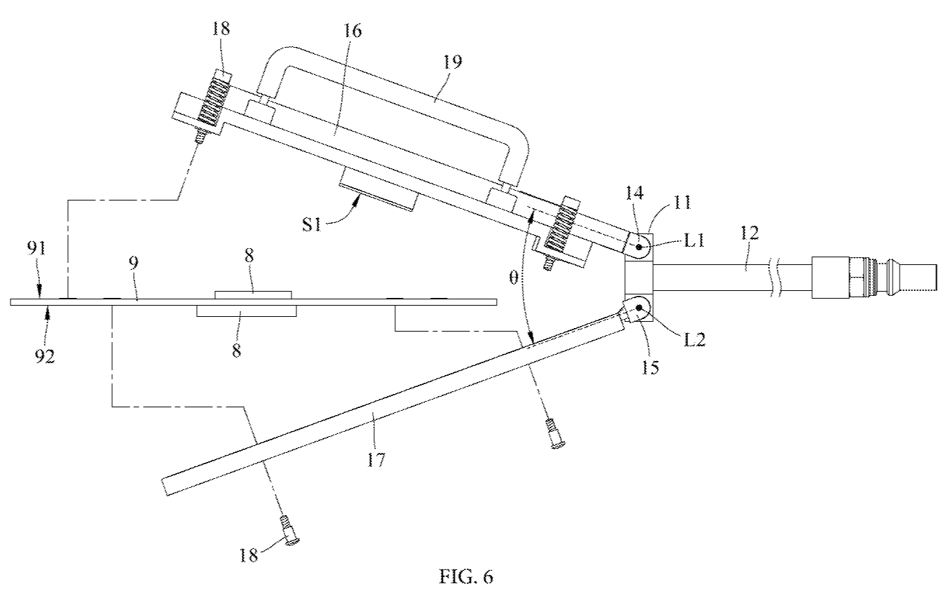

Referring to FIG. 6 along with FIG. 1, FIG. 6 is a side view of the server 1 and the liquid cooling heat dissipation module 10 of FIG. 1 in the open state. The first cold plate 16 is movable via a pivot point along the first axis L1, and the second cold plate 17 is movable via a pivot point along the second axis L2. Accordingly, the first cold plate 16 and the second cold plate 17 are movable relative to each other to place the liquid cooling heat dissipation module 10 in the closed state (as shown in FIG. 1) or the open state (as shown in FIG. 6).

When the liquid cooling heat dissipation module 10 is in the open state, an angle θ between the first cold plate 16 and the second cold plate 17 may be greater than 0 degrees and less than or equal to 180 degrees. For example, the first cold plate 16 and the second cold plate 17 may move relative to each other within a range of 0 degrees to 180 degrees. Therefore, a user can simplify the process for either the removal of the liquid cooling heat dissipation module 10 from the mainboard 9 or installation of the liquid cooling heat dissipation module 10 onto the mainboard 9.

When the liquid cooling heat dissipation module 10 is in the closed state, the first cold plate 16 is substantially parallel to the second cold plate 17, such that the angle θ between the first cold plate 16 and the second cold plate 17 is 0 degrees. Accordingly, the fasteners 18 extend through the first cold plate 16 and the second cold plate 17 and are secured to the mainboard 9, securing the first cold plate 16 and the second cold plate 17 to the mainboard 9 in such a way that the first heat-absorbing surface S1 and the second heat-absorbing surface S2 are respectively in thermal contact with the heat-generating components 8 on the opposite surfaces of the mainboard 9. It should be understood that the manner in which the cold plates are secured to the mainboard is not limited to the fasteners. In one embodiment, the cold plates and the mainboard may be fixed to each other by clips, quick-release fasteners, or other suitable fastening mechanisms.

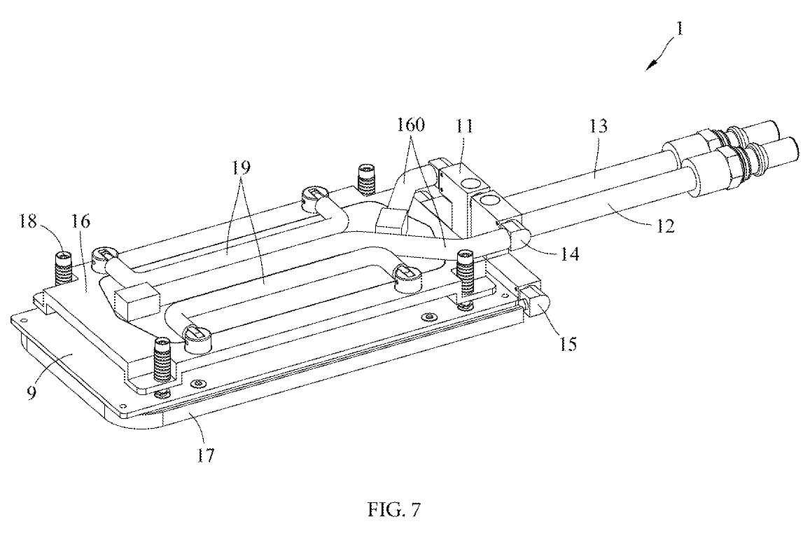

Referring to FIG. 7, FIG. 7 is a perspective view of the liquid cooling heat dissipation module of FIG. 1, illustrating a foldable handle in a folded position. As shown in FIGS. 1 and 7, the two foldable handles 19 are pivotally disposed on a side of the first cold plate 16 opposite the first heat-absorbing surface S1. When a user intends to move the first cold plate 16, the two foldable handles 19 may be unfolded, as shown in FIG. 1, to facilitate manual pulling or rotation of the first cold plate 16. Conversely, when the liquid cooling heat dissipation module 10 is in the closed state, the two foldable handles 19 may be folded to reduce an overall thickness of the liquid cooling heat dissipation module 10 and improve space utilization efficiency, as shown in FIG. 7. It should be understood that the foldable handles are optional and, in some embodiments, the liquid cooling heat dissipation module may be provided without foldable handles.

In one embodiment, both the first cold plate 16 and the second cold plate 17 are pivotally coupled to the manifold assembly 11. However, the embodiment is not limited thereto. In other embodiments, only one of the cold plates may be configured to be pivotable, while the other cold plate is non-pivotably coupled. For example, the first cold plate of the liquid cooling heat dissipation module is pivotally coupled to the manifold assembly, and the second cold plate is fixedly connected to the manifold assembly, such that the first cold plate is movable relative to the second cold plate to place the liquid cooling heat dissipation module in an open state or a closed state. Accordingly, when the liquid cooling heat dissipation module is in the open state, an angle between the first cold plate and the second cold plate may be greater than 0 degrees and less than or equal to 90 degrees. For example, the first cold plate and the second cold plate may rotate relative to each other within a range of 0 degrees to 90 degrees.

It should also be understood that, when the second cold plate is non-pivotable, the liquid cooling heat dissipation module may not include the pivotable second nozzles, and opposite ends of the metal tube may be directly and fixedly connected to the distribution ports of the distribution manifold and the collection ports of the collection manifold. Alternatively, the second cold plate may be fixedly connected to the distribution ports and the collection ports via non-pivotable second nozzles.

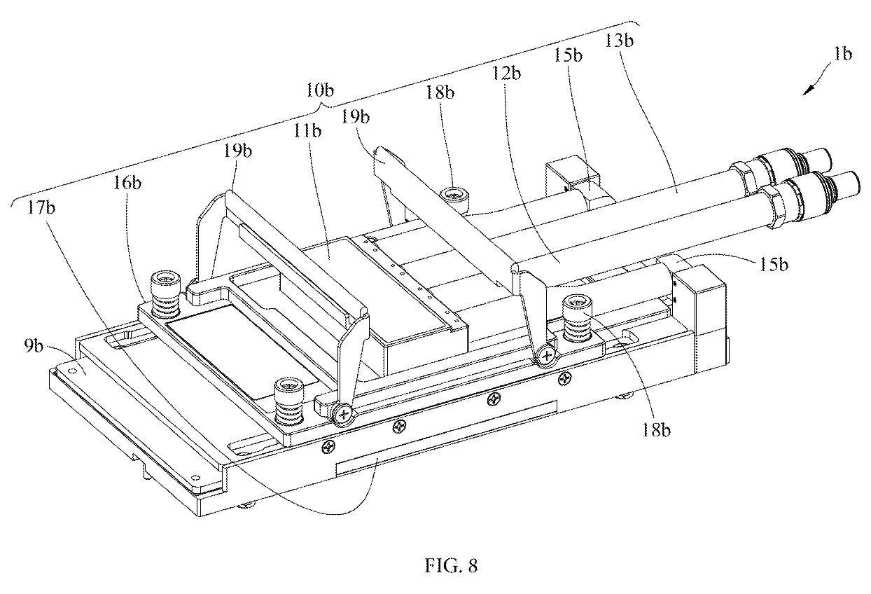

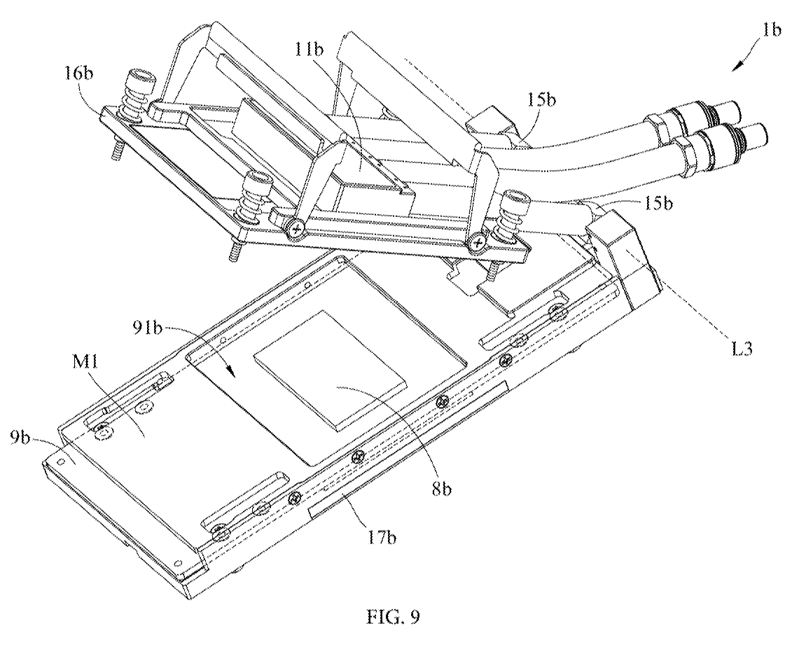

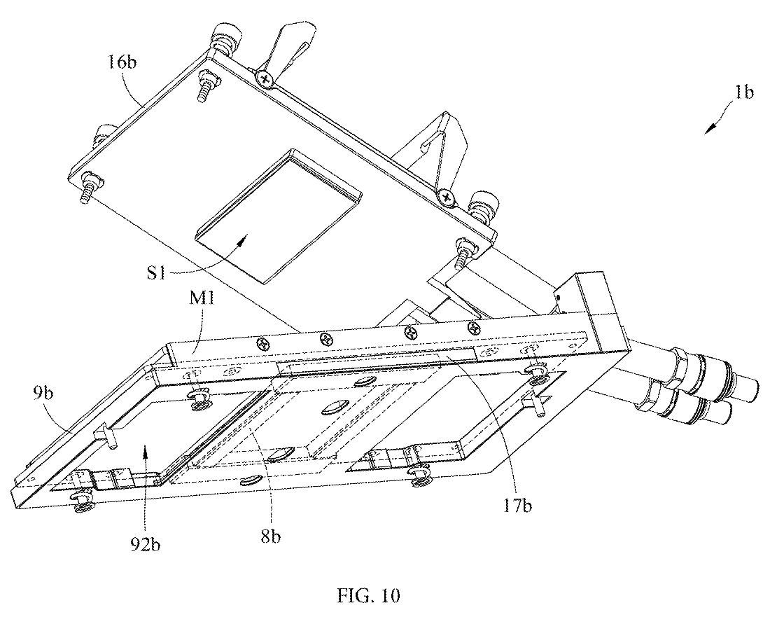

Referring to FIGS. 8-10, FIG. 8 is a partial perspective view of a server 1b and a liquid cooling heat dissipation module 10b thereof in a closed state, in accordance with one embodiment of the present disclosure. FIG. 9 is a perspective view of the server 1b and the liquid cooling heat dissipation module 10b of FIG. 8 in an open state. FIG. 10 is another perspective view of the server 1b and the liquid cooling heat dissipation module 10b of FIG. 8 in the open state.

In one embodiment, the server 1b includes a mainboard 9b, a plurality of heat-generating components 8b, and a liquid cooling heat dissipation module 10b. The mainboard 9b has a first surface 91b and a second surface 92b opposite to each other, and the heat-generating components 8b are respectively disposed on the first surface 91b and the second surface 92b. The liquid cooling heat dissipation module 10b is configured to cool the heat-generating components 8b located on the opposite surfaces of the mainboard 9b. The heat-generating components 8b may include a central processing unit (CPU), a graphics processing unit (GPU), a voltage regulator module (VRM), or any suitable electronic devices.

In one embodiment, the liquid cooling heat dissipation module 10b includes a manifold assembly 11b, a main inlet conduit 12b, a main outlet conduit 13b, two second nozzles 15b, a first cold plate 16b, a second cold plate 17b, a plurality of fasteners 18b, and two foldable handles 19b. The manifold assembly 11b is configured to be in fluid communication with a heat exchanger (not separately shown) and to distribute and collect working fluid.

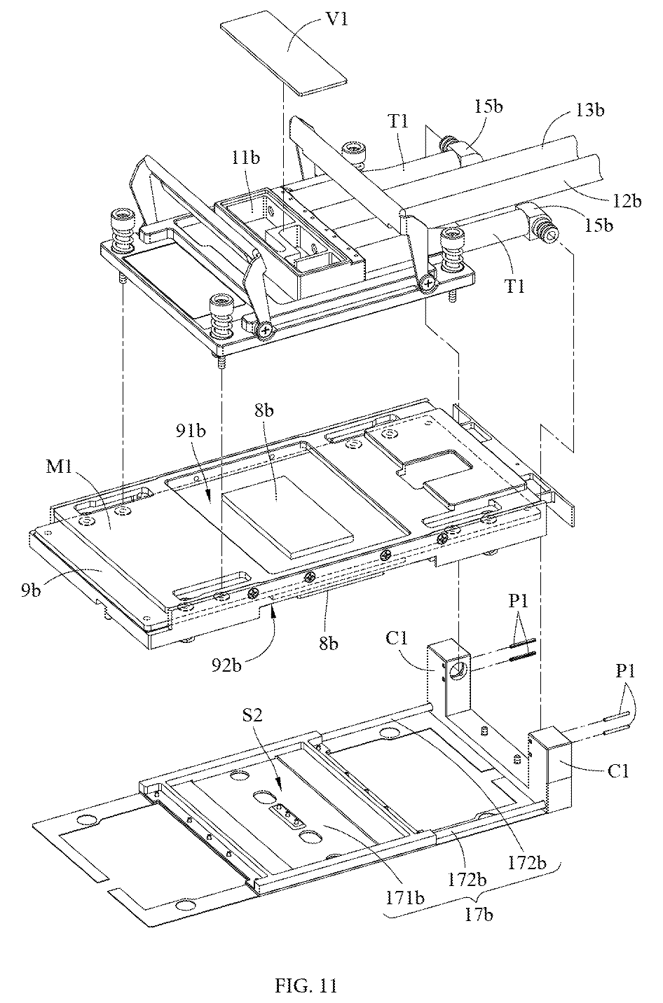

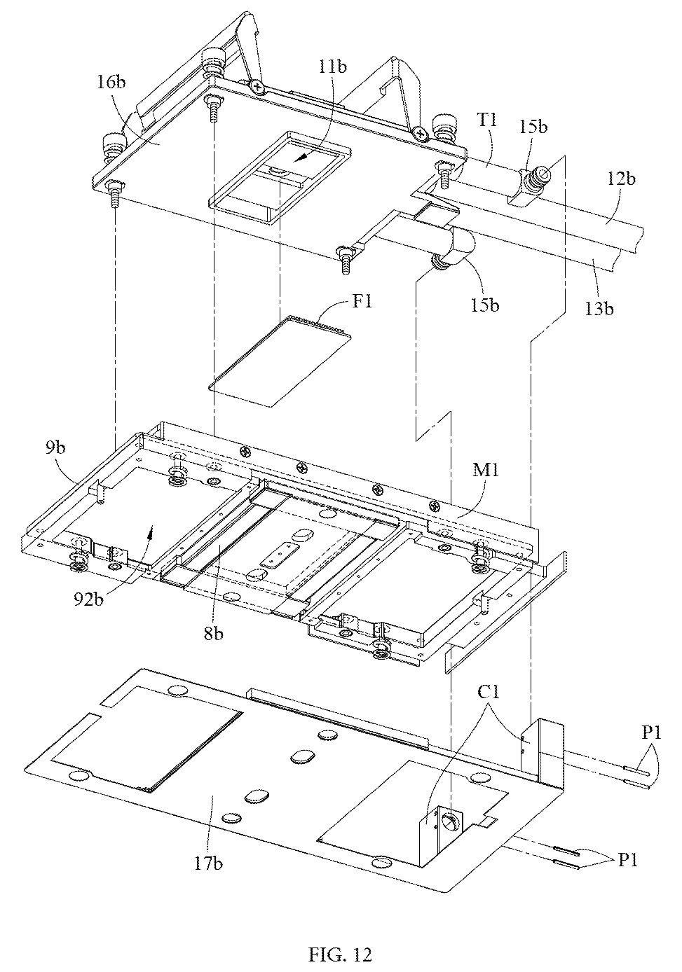

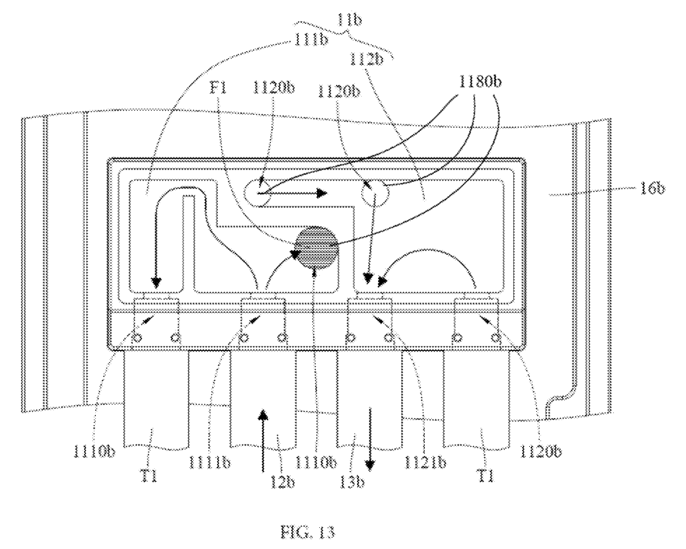

Referring to FIGS. 11-13, FIG. 11 is an exploded view of the liquid cooling heat dissipation module of FIG. 8. FIG. 12 is another exploded view of the liquid cooling heat dissipation module of FIG. 8. FIG. 13 is a top view of a manifold assembly of FIG. 11 with an upper cover removed.

In one embodiment, the manifold assembly 11b includes a distribution manifold 111b and a collection manifold 112b. The distribution manifold 111b has a main inlet port 1111b in fluid communication with two distribution ports 1110b, and the collection manifold 112b has a main outlet port 1121b in fluid communication with three collection ports 1120b. Specifically, the distribution manifold 111b is configured to distribute working fluid flowing from the main inlet port 1111b to the two distribution ports 1110b, and the collection manifold 112b is configured to collect the working fluid flowing from the three collection ports 1120b into the main outlet port 1121b. The distribution manifold 111b and the collection manifold 112b are fixedly connected to each other. However, the embodiment is not limited thereto. In other embodiments, the distribution manifold and the collection manifold of the manifold assembly may be provided separately.

In one embodiment, opposite ends of the main inlet conduit 12b are respectively connected to the main inlet port 1111b of the distribution manifold 111b and to a heat exchanger, guiding the working fluid cooled by the heat exchanger to the distribution manifold 111b of the manifold assembly 11b. Opposite ends of the main outlet conduit 13b are respectively connected to the main outlet port 1121b of the collection manifold 112b and to the heat exchanger guiding the heated working fluid from the collection manifold 112b of the manifold assembly 11b to the heat exchanger.

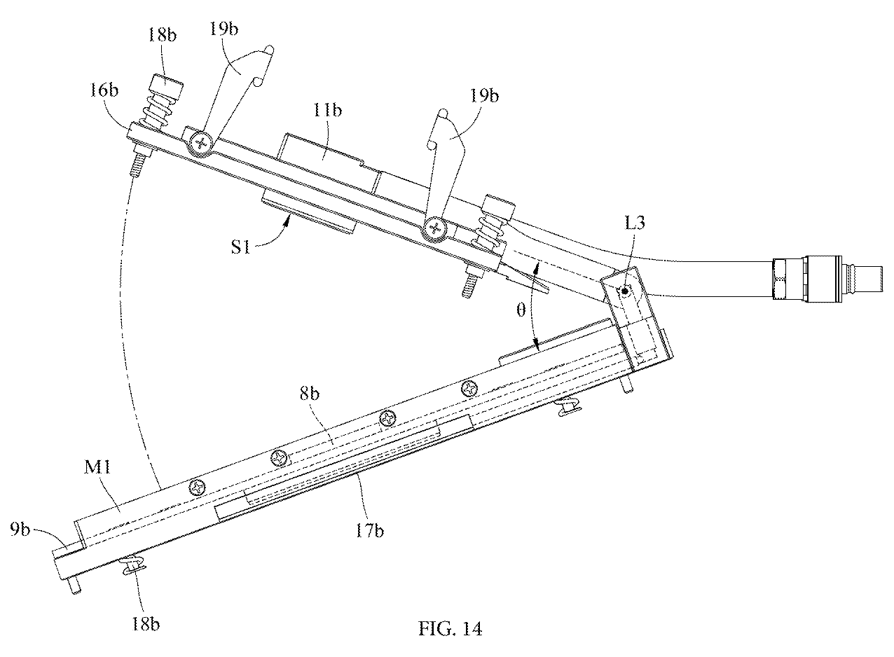

In one embodiment, the first cold plate 16b is in fluid communication with the manifold assembly 11b to allow working fluid to flow therethrough and is in thermal contact with the heat-generating components 8b on the first surface 91b of the mainboard 9b. As shown in FIG. 12, the manifold assembly 11b is disposed on a side of the first cold plate 16b facing away from the mainboard 9b and secured to the first cold plate 16b. The first cold plate 16b includes an internal chamber, three through holes 1180b, and a first heat-absorbing surface S1 (as shown in FIG. 14). The three through holes 1180b are in fluid communication with the internal chamber and are respectively connected to one of the distribution ports 1110b of the distribution manifold 111b and to two of the collection ports 1120b of the collection manifold 112b, allowing the internal chamber of the first cold plate 16b to fluidly communicate with the manifold assembly 11b. The first heat-absorbing surface S1 is in thermal contact with the heat-generating components 8b on the first surface 91b of the mainboard 9b, transferring heat generated by the heat-generating components 8b to the working fluid within the internal chamber via the first heat-absorbing surface S1.

In one embodiment, after the working fluid enters the first cold plate 16b from the distribution manifold 111b, the working fluid flows within the internal chamber in an impinging-flow manner, allowing the working fluid to impinge substantially vertically on heat-dissipating fins F1 disposed in the internal chamber and then spread laterally along the heat-dissipating fins F1. The working fluid subsequently converges toward a central region via guide grooves formed on opposite sides of the internal chamber and then returns to the collection manifold 112b through the through holes 1180b of the first cold plate 16b and the collection ports 1120b in fluid communication therewith.

In one embodiment, the second cold plate 17b is in fluid communication with the manifold assembly 11b to allow the working fluid to flow therethrough and is in thermal contact with the heat-generating components 8b on the second surface 92b of the mainboard 9b.The second cold plate 17b includes a metal plate body 171b and two metal tubes 172b. The metal plate body 171b has a plurality of internal fluid channels and a second heat-absorbing surface S2. One end of each metal tubes 172b is respectively connected to opposite ends of the internal fluid channels, and the other end of each metal tube 172b is provided with a connector C1. The second heat-absorbing surface S2 is in thermal contact with the heat-generating components 8b on the second surface 92b of the mainboard 9b, transferring heat generated by the heat-generating components 8b to the working fluid flowing through the internal fluid channels. The metal tubes 172b may be formed of copper or other suitable materials, and the metal plate body 171b may be formed of aluminum or copper or other suitable materials.

In one embodiment, the two second nozzles 15b are respectively rotatably coupled to the two connectors C1. The other distribution port 1110b of the distribution manifold 111b is connected to one of the second nozzles 15b via a connecting tube T1, and the other collection port 1120b of the collection manifold 112b is connected to the other second nozzle 15b via another connecting tube T1. Accordingly, the second cold plate 17b is pivotally coupled to the manifold assembly 11b via the two second nozzles 15b and the connecting tubes T1, and the metal tubes 172b of the second cold plate 17b are in fluid communication with the manifold assembly 11b through the two second nozzles 15b.

In one embodiment, each of the second nozzles 15b is a barb-type nozzle having multiple barbed layers, and a plurality of sealing rings are fixedly sleeved on the barbed portion of each second nozzle 15b. After the barbed portion of each second nozzle 15b is inserted into the corresponding connector C1, a pin P1 is inserted into the connector C1 so as to interfere with the barbed structure in an insertion direction, preventing the barb-type nozzle from being unintentionally disengaged from the connector C1 and simultaneously preventing leakage of the working fluid. Additionally, the second nozzle 15b and the pin P1 do not interfere with each other in a circumferential direction of the barbed portion, allowing the second nozzle 15b to rotate freely within the connector C1.

Therefore, the second cold plate 17b is pivotally and indirectly coupled to the manifold assembly 11b, and the first cold plate 16b and the second cold plate 17b respectively cooperate with the manifold assembly 11b and the heat exchanger to form two parallel cooling loops. The second cold plate 17b is movable relative to the first cold plate 16b to position the liquid cooling heat dissipation module 10b in a closed state or an open state.

Referring to FIG. 14 along with FIG. 8, FIG. 14 is a side view of the server and the liquid cooling heat dissipation module of FIG. 8 in the open state. As shown in FIG. 14, the first cold plate 16b and the manifold assembly 11b are collaborate together for allowing the first cold plate 16b to move relative to the second cold plate 17b along a third axis L3. The third axis L3 is distinct from the first axis L1 and second axis L2. Accordingly, the first cold plate 16b is movable relative to the second cold plate 17b to position the liquid cooling heat dissipation module 10b in a closed state (as shown in FIG. 8) or an open state (as shown in FIG. 14).

When the liquid cooling heat dissipation module 10b is in the open state, the angle θ between the first cold plate 16b and the second cold plate 17b may be greater than 0 degrees and less than or equal to 90 degrees. For example, the first cold plate 16b and the second cold plate 17b may be relative to each other within a range of 0 degrees to 90 degrees. Therefore, a user can facilitate the removal of the liquid cooling heat dissipation module 10b from the mainboard 9b and assembly of the liquid cooling heat dissipation module 10b onto the mainboard 9b.

When the liquid cooling heat dissipation module 10b is in the closed state, the first cold plate 16b is substantially parallel to the second cold plate 17b, such that the angle θ between the first cold plate 16b and the second cold plate 17b is 0 degrees. Accordingly, the fasteners 18b extend through the first cold plate 16b and the second cold plate 17b and are secured to the mainboard 9b, securing the first cold plate 16b and the second cold plate 17b to the mainboard 9b in such a way that the first heat-absorbing surface S1 and the second heat-absorbing surface S2 are respectively in thermal contact with the heat-generating components 8b on opposite surfaces of the mainboard 9b.

In one embodiment, the mainboard 9b is additionally mounted to the second cold plate 17b via a mounting frame M1. However, the embodiment is not limited thereto. In other embodiments, the cold plates and the mainboard may be fixed to each other by clips, quick-release fasteners, or other suitable fastening mechanisms.

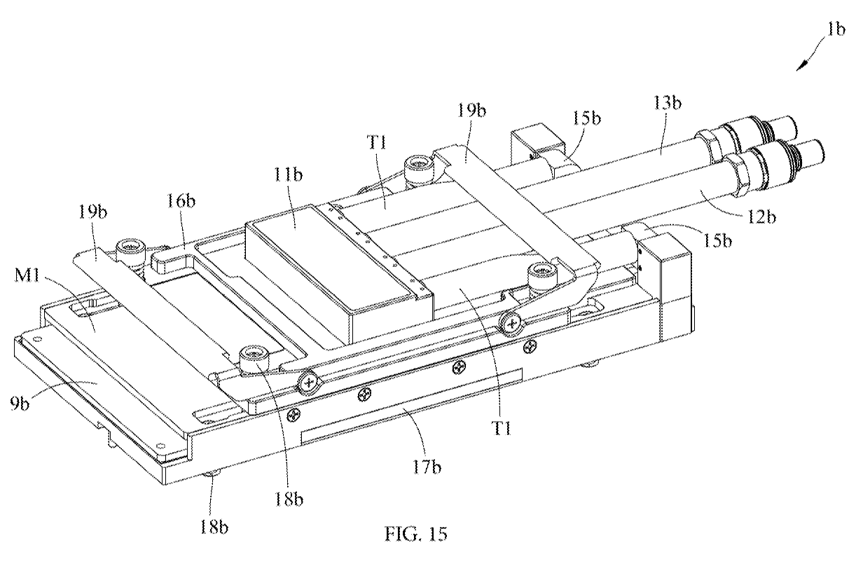

Referring to FIG. 15 along with FIGS. 8 and 13, FIG. 15 is a perspective view of the liquid cooling heat dissipation module of FIG. 8, illustrating a foldable handle in a folded position. As shown in FIGS. 8 and 15, the two foldable handles 19b are pivotally disposed on a side of the first cold plate 16b opposite the first heat-absorbing surface S1. When a user intends to move the first cold plate 16b, the two foldable handles 19b may be unfolded, as shown in FIG. 8, to facilitate manual pulling or rotation of the first cold plate 16b. Conversely, when the liquid cooling heat dissipation module 10b is in the closed state, the two foldable handles 19b may be folded, as shown in FIG. 15, to reduce an overall thickness of the liquid cooling heat dissipation module 10b and improve space utilization efficiency.

It should be understood that the foldable handles are optional, and the embodiment is not limited thereto. In other embodiments, the liquid cooling heat dissipation module may be provided without foldable handles.

In one embodiment, the first cold plate 16b includes two through holes 1180b connected to two collection ports 1120b of the collection manifold 112b. However, the embodiment is not limited thereto. In other embodiments, the first cold plate may include only one through hole in fluid communication with the collection manifold, and the collection manifold may include only one collection port in fluid communication with the first cold plate.

In one embodiment, the first cold plate 16b and the second cold plate 17b respectively collaborate with the manifold assembly 11b and the heat exchanger to form two parallel cooling loops. However, the present invention is not limited thereto. In other embodiments, the first cold plate and the second cold plate may be fluidly coupled in series, partially in series, or in a hybrid configuration with respect to the manifold assembly and the heat exchanger.

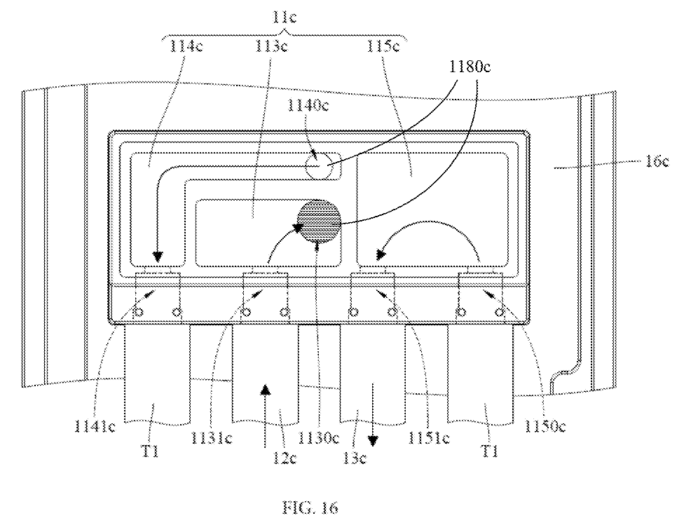

FIG. 16 is a top view of a manifold assembly with an upper cover removed in accordance with one embodiment of the present disclosure. As shown in FIG. 16, the manifold assembly 11c includes a first flow-guiding conduit 113c, a second flow-guiding conduit 114c, and a third flow-guiding conduit 115c. The first flow-guiding conduit 113c has a first inlet port 1131c as a main inlet port in fluid communication with a first port 1130c, the second flow-guiding conduit 114c has a second inlet port 1140c in fluid communication with a second outlet port 1141c, and the third flow-guiding conduit 115c has a first outlet port 1151c as a main outlet port in fluid communication with a third port 1150c.

Specifically, the first flow-guiding conduit 113c is configured to guide a working fluid flowing from the main inlet port 1131c to the first port 1130c, the second flow-guiding conduit 114c is configured to guide the working fluid flowing from the second inlet port 1140c to the second outlet port 1141c, and the third flow-guiding conduit 115c is configured to guide the working fluid flowing from the third port 1150c to the main outlet port 1151c. In one embodiment, the first flow-guiding conduit 113c, the second flow-guiding conduit 114c, and the third flow-guiding conduit 115c are securely connected to one another. However, the embodiment is not limited thereto. In other embodiments, the first, second, and third flow-guiding conduits of the manifold assembly may be provided separately.

In one embodiment, opposite ends of the main inlet conduit 12c are respectively connected to the main inlet port 1131c of the first flow-guiding conduit 113c and to a heat exchanger to guide the working fluid cooled by the heat exchanger to the first flow-guiding conduit 113c of the manifold assembly 11c. Opposite ends of the main outlet conduit 13c are respectively connected to the main outlet port 1151c of the third flow-guiding conduit 115c and to the heat exchanger to guide the heated working fluid from the third flow-guiding conduit 115c of the manifold assembly 11c to the heat exchanger.

In one embodiment, two through holes 1180c of the first cold plate 16c are respectively connected to the first port 1130c of the first flow-guiding conduit 113c and to the second inlet port 1140c of the second flow-guiding conduit 114c, allowing an internal chamber of the first cold plate 16c to communicate fluidly with the manifold assembly 11c.

In one embodiment, the second outlet port 1141c of the second flow-guiding conduit 114c is connected to one of the second nozzles via a connecting tube T1, and the third port 1150c of the third flow-guiding conduit 115c is connected to the other second nozzle via another connecting tube T1. Accordingly, a metal tube of the second cold plate is in fluid communication with the manifold assembly 11c through the two second nozzles.

Therefore, the first cold plate 16c, the second cold plate, the manifold assembly 11c, and the heat exchanger cooperatively form a series cooling loop. Specifically, the working fluid from the heat exchanger enters the first flow-guiding conduit 113c of the manifold assembly 11c through the main inlet conduit 12c and the main inlet port 1131c, flows into the first cold plate 16c through the first port 1130c, and absorbs heat within the first cold plate 16c. The working fluid then flows into the second flow-guiding conduit 114c through the second inlet port 1140c, and flows to the second cold plate through the second outlet port 1141c and one of the connecting tubes T1. After absorbing heat in the second cold plate, the working fluid flows back to the third flow-guiding conduit 115c of the manifold assembly 11c through the other connecting tube T1 and the third port 1150c, exits the manifold assembly 11c through the main outlet port 1151c, and is guided to the heat exchanger through the main outlet conduit 13c for cooling, forming the series cooling loop.

According the present disclosure, at least one of the first cold plate and the second cold plate is pivotally coupled to the manifold assembly, such that the first cold plate and the second cold plate are movable relative to each other to position the liquid cooling heat dissipation module in a closed state or an open state. As a result, uniform heat dissipation for heat-generating components disposed on opposite surfaces of the mainboard can be achieved while also enabling the streamlined removal and installation of the liquid cooling heat dissipation module.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A liquid cooling heat dissipation module, comprising:
a manifold assembly configured to be in fluid communication with a heat exchanger and to distribute and collect a working fluid;
a first cold plate in fluid communication with the manifold assembly, the first cold plate being configured to thermally contact heat-generating components disposed on a first surface of the mainboard; and
a second cold plate in fluid communication with the manifold assembly, the second cold plate being configured to thermally contact heat-generating components disposed on a second surface of the mainboard;
wherein the first cold plate is pivotally coupled to the manifold assembly, and the second cold plate is securely connected to the manifold assembly.

2. The liquid cooling heat dissipation module of claim 1, wherein:
the first cold plate is movable relative to the second cold plate to position the liquid cooling heat dissipation module in the open state or the closed state,
when the liquid cooling heat dissipation module is in the open state, an included angle between the first cold plate and the second cold plate is greater than 0 degrees and less than or equal to 90 degrees, and
when the liquid cooling heat dissipation module is in the closed state, the included angle between the first cold plate and the second cold plate is 0 degrees.

3. The liquid cooling heat dissipation module of claim 1, wherein the manifold assembly includes:
a distribution manifold having a main inlet port in fluid communication with two distribution ports, and
a collection manifold having a main outlet port in fluid communication with two collection ports.

4. The liquid cooling heat dissipation module of claim 3, further comprising:
a main inlet conduit having opposing ends respectively connected to the main inlet port and the heat exchanger;
a main outlet conduit having opposing ends respectively connected to the main outlet port and the heat exchanger; and
two first nozzles respectively rotatably coupled to a first distribution port and a first collection port.

5. The liquid cooling heat dissipation module of claim 4, wherein:
the first cold plate includes an internal flow channel having opposite ends respectively connected to the two first nozzles via two connecting pipes, and
the second cold plate includes a metal plate body and a metal tube embedded in the metal plate body, opposite ends of the metal tube being securely connected to a second distribution port and a second collection port.

6. The liquid cooling heat dissipation module of claim 1, further comprising at least one flow-guiding conduit in fluid communication with the manifold assembly, wherein the first cold plate and the second cold plate are fluidly coupled to the heat exchanger through the manifold assembly and the at least one flow-guiding conduit to define at least one cooling loop.

7. The liquid cooling heat dissipation module of claim 1, further comprising a foldable handle pivotally disposed on the first cold plate.

8. The liquid cooling heat dissipation module of claim 1, further comprising a plurality of fasteners extending through the first cold plate and the second cold plate and securing the first cold plate and the second cold plate to the mainboard when the liquid cooling heat dissipation module is in the closed state.

9. A liquid cooling heat dissipation module, comprising:
a manifold assembly having a distribution manifold and a collection manifold ;
a first cold plate in fluid communication with the manifold assembly, the first cold plate being configured to thermally contact heat-generating components disposed on a first surface of the mainboard; and
a second cold plate in fluid communication with the manifold assembly, the second cold plate being configured to thermally contact heat-generating components disposed on a second surface of the mainboard, wherein both the first cold plate and the second cold plate are pivotally coupled to the manifold assembly.

10. The liquid cooling heat dissipation module of claim 9, wherein:
when the liquid cooling heat dissipation module is in the open state, an included angle between the first cold plate and the second cold plate is greater than 0 degrees and less than or equal to 180 degrees, and
when the liquid cooling heat dissipation module is in the closed state, the included angle between the first cold plate and the second cold plate is 0 degrees.

11. The liquid cooling heat dissipation module of claim 10, wherein:
the first cold plate is rotatable about a first axis extending through the manifold assembly;
the second cold plate is rotatable about a second axis extending through the manifold assembly; and
the first axis is parallel to the second axis.

12. The liquid cooling heat dissipation module of claim 11, further comprising:
a main inlet conduit; and
a main outlet conduit, wherein one end of the main inlet conduit and one end of the main outlet conduit are respectively connected to the heat exchanger.

13. The liquid cooling heat dissipation module of claim 11, further comprising:
two first nozzles rotatable along the first axis; and
two second nozzles rotatable along the second axis;
wherein the first cold plate includes a first internal flow channel connected to the two first nozzles via connecting pipes, and the second cold plate comprises a metal plate body and a metal tube having opposite ends securely connected to the two second nozzles.

14. The liquid cooling heat dissipation module of claim 9, further comprising at least one flow-guiding conduit in fluid communication with the manifold assembly, wherein the first cold plate and the second cold plate are fluidly coupled to the heat exchanger through the manifold assembly and the at least one flow-guiding conduit to form at least one cooling loop.

15. The liquid cooling heat dissipation module of claim 9, further comprising a foldable handle pivotally disposed on the first cold plate.

16. A server comprising:
a mainboard having a first surface and a second surface opposite the first surface;
a plurality of heat-generating components disposed on the first surface and the second surface; and
a liquid cooling heat dissipation module, including:
a manifold assembly configured to be in fluid communication with a heat exchanger and to distribute and collect a working fluid;
a first cold plate in fluid communication with the manifold assembly, the first cold plate being configured to thermally contact heat-generating components disposed on the first surface of the mainboard; and
a second cold plate in fluid communication with the manifold assembly, the second cold plate being configured to thermally contact heat-generating components on the second surface of the mainboard, wherein the first cold plate is pivotally coupled to the manifold assembly, and the second cold plate is securely connected to the manifold assembly.

17. The server of claim 16, wherein:
the first cold plate is movable relative to the second cold plate to position the liquid cooling heat dissipation module in the open state or the closed state,
when the liquid cooling heat dissipation module is in the open state, an included angle between the first cold plate and the second cold plate is greater than 0 degrees and less than or equal to 90 degrees, and
when the liquid cooling heat dissipation module is in the closed state, the included angle between the first cold plate and the second cold plate is 0 degrees.

18. The server of claim 16, wherein the manifold assembly includes:
a distribution manifold having a main inlet port in fluid communication with two distribution ports, and
a collection manifold having a main outlet port in fluid communication with two collection ports.

19. The server of claim 18, further comprising:
a main inlet conduit having opposing ends respectively connected to the main inlet port and the heat exchanger;
a main outlet conduit having opposing ends respectively connected to the main outlet port and the heat exchanger; and
two first nozzles respectively rotatably coupled to a first distribution port and a first collection port.

20. The server of claim 18, wherein:
the first cold plate includes an internal flow channel having opposite ends respectively connected to the two first nozzles via two connecting pipes, and
the second cold plate includes a metal plate body and a metal tube embedded in the metal plate body, opposite ends of the metal tube being securely connected to a second distribution port and a second collection port.
